(19) United States
(12) Patent Application Publication
(10) Pub. No.: US 2009/0269926 A1
(43) Pub. Date: Oct. 29, 2009

(54) POLYGRAIN ENGINEERING BY ADDING IMPURITIES IN THE GAS PHASE DURING CHEMICAL VAPOR DEPOSITION OF POLYSILICON

(75) Inventors: Abhishek Dube, Fishkill, NY (US); Ashima B. Chakravarti, Hopewell Junction, NY (US); Anthony I. Chou, Beacon, NY (US); Wei He, Fishkill, NY (US); Dominic J. Schepis, Wappingers Falls, NY (US)

Correspondence Address: FREDERICK W. GIBB, III;Gibb Intellectual Property Law Firm, LLC, 2568-A RIVA ROAD, SUITE 304, ANNAPOLIS, MD, 21401, US

(73) Assignee: INTERNATIONAL BUSINESS MACHINES CORPORATION, Armonk, NY (US)

(21) Appl. No.: 12/110,594

(22) Filed: Apr. 28, 2008

(51) Int. Cl. H01L 21/44

(52) U.S. Cl. 438/680; 257/E21.476

(57) ABSTRACT

A method of forming at least one gate conductor of a complementary metal oxide semiconductor performs a chemical vapor deposition process of polysilicon over a surface where a polysilicon gate is to be located. This deposition can be performed through a mask to form gate structures directly, or a later patterning process can pattern the polysilicon into gate structures. During the chemical vapor deposition process, the method adds impurities in the chemical vapor deposition process to optimize the grain size of the polysilicon according to a number of different methods.

### BACKGROUND

1. Field of the Invention

The embodiments of the invention generally relate to methods of forming a gate conductor of a complementary metal oxide semiconductor and more particularly to methods that selectively introduce impurities into a polysilicon deposition process to optimize the grain size of the polysilicon.

2. Description of the Related Art

Current complementary metal oxide semiconductor (CMOS) scaling trends require the polysilicon gate length to become smaller with successive generations of technology. In fact, state of the art high performance logic uses gates that are well below 100 nm. On the other hand, standard polysilicon grains sizes are approximately 400-700 A. This implies that the grain size of polysilicon is approaching the same dimensions as the physical dimension of the gate itself.

### SUMMARY

In order to address such issues, disclosed herein are methods of forming at least one gate conductor of a complementary metal oxide semiconductor. One method embodiment herein performs a chemical vapor deposition (CVD) process of polysilicon over a surface where a polysilicon gate is to be located. This deposition can be performed through a mask to form gate structures directly, or a later patterning process can pattern the polysilicon into gate structures. During the chemical vapor deposition process, the method adds impurities in the chemical vapor deposition process to optimize the grain size of the polysilicon according to a number of different methods. For example, the impurities can comprise NH₃, Methyl Silane, C₂H₆ and Germanium, or a mixture, such as a mixture of BTBAS and SiH₄.

One of the different methods can simply add the impurities at any point or continuously throughout the chemical vapor deposition process. Alternatively, the chemical vapor deposition process can be paused, the impurities can be added (possibly in one or more short bursts) and then the chemical vapor deposition process can be restarted. This pausing process can be repeated a number of times to achieve desired results.

An alternative method can use a multi-stage chemical vapor deposition process to create a bi-layer polysilicon gate structure. Thus, this method also performs the multi-stage chemical vapor deposition process of polysilicon over the surface where the polysilicon gate is to be located. This multi-stage chemical vapor deposition process comprises: a first chemical vapor deposition stage during which the impurities are added in the chemical vapor deposition process; a second chemical vapor deposition stage comprising depositing pure polysilicon; and a third chemical vapor deposition stage again during which the impurities are added in the chemical vapor deposition process. While three stages are discussed here, any of the stages can be repeated as desired to achieve any specific polysilicon grain size desired. Further, the order of the steps can be changed so the first and last stages comprise pure polysilicon deposition. Also, during the stages where impurities are added, such can be added according to any of the previously mentioned methods, including pausing while adding the impurities in one or more bursts.

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a flow diagram illustrating a method embodiment of the invention; and

FIG. 2 is a flow diagram illustrating a method embodiment of the invention.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

As mentioned above, current CMOS scaling trends require the polysilicon gate length to become smaller with successive generations of technology. Another feature of CMOS scaling is concurrent electrical thinning of the gate oxide. One disadvantage of using polysilicon as the gate conductor is that the polysilicon becomes depleted in the region of the SiO₂-polysilicon interface as a result of channel inversion. The unwanted depletion is an effective electrical thickening of the gate oxide. Increasing gate activation minimizes polysilicon depletion effects. Therefore, it is desirable to improve polysilicon gate activation. One possible technique to improve polysilicon depletion is to have more active dopants at the SiO₂-polysilicon interface.

Dopants arrive at the SiO₂-Polysilicon interface by two pathways. One path is diffusion in the crystal polysilicon, the other path is via the grain boundary diffusion. Diffusion in grain boundaries is much faster than diffusion within the polysilicon crystal. Since gate dimensions are about the same size as the polysilicon grain sizes, most of the diffusion takes place within the crystal rather than the grain boundary for nominal size transistors. This means that polysilicon depletion may be improved for nominal gates by using polysilicon with smaller grain sizes. Also, small grain will give more uniform dopant diffusion toward gate oxide, enable better reliability and threshold voltage control. This is in addition to the point that more efficient diffusion reduces polysilicon depletion.

In order to address issues of gain size in the polysilicon gates, this disclosure presents methods to optimize the grain size by adding different impurities in the gas mixture of the chemical vapor deposition process. With embodiments herein grain sizes are altered in the CVD system 1) by adding some gaseous precursors, like NH₃ for N, methyl silane, C₂H₆, etc. for C, etc., in the gas mixture during the deposition process; 2) by interrupting the process and inserting a dopant precursor (without the SI precursor flow) in a short burst; 3) by producing a layered structure using a multi-stage chemical vapor deposition process (e.g., Si precursor flow; Si precursor+dopant flow; Si precursor flow/etc); 4) by mixing different precursors like BTBAS and SiH₄; and 5) by adding small amount of other impurities like Germanium.

One idea with the embodiments here is that when there are impurities present, the growing of large crystals will be interrupted by the impurities. With embodiments herein the presence of elements with very different atomic size, e.g., C, Ge, etc. will prevent continuous growth of large Si crystal. These can be done easily in a single wafer CVD tool.

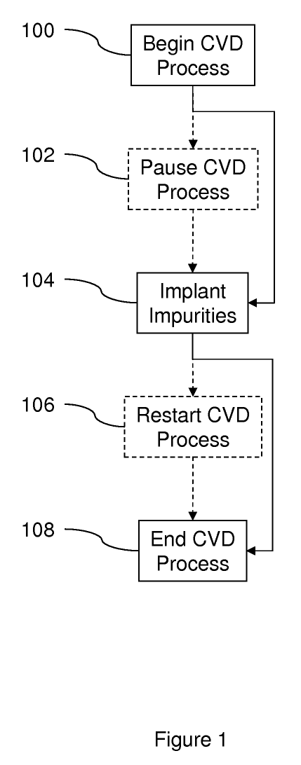

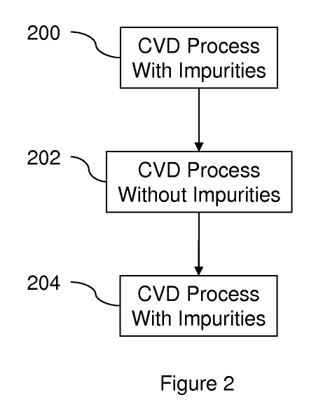

The foregoing processes are shown in flowchart form in FIGS. 1 and 2, that are discussed below. More specifically, FIGS. 1 and 2 disclosed methods of forming at least one gate conductor of a complementary metal oxide semiconductor.

As shown in FIG. 1, one method embodiment herein begins a chemical vapor deposition process of polysilicon 100 over a surface where a polysilicon gate is to be located. This deposition can be performed through a mask to form gate structures directly, or a later patterning process can pattern the polysilicon into gate structures. During the chemical vapor deposition process 100, the method adds impurities 104 in the chemical vapor deposition process to optimize the grain size of the polysilicon according to a number of different methods. The chemical vapor deposition process ends in item 108. For example, the impurities can comprise NH₃, Methyl Silane, C₂H₆ and Germanium, or a mixture, such as a mixture of bis(tertiary-butylamino silane) (BTBAS) and SiH₄.

The above method simply adds the impurities 104 at any point or continuously throughout the chemical vapor deposition process 100. Alternatively, after the chemical vapor deposition process is started in item 100 the deposition process can optionally be paused in item 102. The impurities 104 are then added (possibly in one or more short bursts) and then the chemical vapor deposition process is restarted in item 106. The chemical vapor deposition process ends in item 108. These pausing 102, adding 104, and restarting 106 processes can be repeated a number of times to achieve desired results.

An alternative method, shown in FIG. 2, can use a multi-stage chemical vapor deposition process to create a bi-layer polysilicon gate structure. Thus, this method also performs the multi-stage chemical vapor deposition process of polysilicon over the surface where the polysilicon gate is to be located. This multi-stage chemical vapor deposition process comprises: a first chemical vapor deposition stage 200 during which the impurities are added in the chemical vapor deposition process; a second chemical vapor deposition stage 202 comprising depositing pure polysilicon; and a third chemical vapor deposition stage 204 again during which the impurities are added in the chemical vapor deposition process. While three stages are discussed here, any of the stages can be repeated as desired to achieve any specific polysilicon grain size desired. Further, the order of the changed so the first and last stages comprise pure polysilicon deposition. Also, during the stages where impurities are added, such can be added according to any of the previously mentioned methods, including pausing while adding the impurities in one or more bursts.

Therefore, as shown above, in order to address issues of gain size in the polysilicon gates, this disclosure presents methods to optimize the grain size by adding different impurities in the gas mixture of the chemical vapor deposition process.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of embodiments, those skilled in the art will recognize that the embodiments of the invention can be practiced with modification within the spirit and scope of the appended claims.

1. A method of forming at least one gate conductor of a complementary metal oxide semiconductor, said method comprising:
performing a chemical vapor deposition process of polysilicon over a surface where a polysilicon gate is to be located; and
during said chemical vapor deposition process, adding impurities in said chemical vapor deposition process,
wherein said impurities comprise one of NH₃, Methyl Silane, C₂H₆, Germanium, and a mixture of BTBAS and SiH₄.

2. The method according to claim 1, wherein said adding of said impurities comprises:
pausing said chemical vapor deposition process;
adding said impurities; and
restarting said chemical vapor deposition process.

3. (canceled)

4. A method of forming at least one gate conductor of a complementary metal oxide semiconductor, said method comprising:
performing a multi-stage chemical vapor deposition process of polysilicon over a surface where a polysilicon gate is to be located, wherein said multi-stage chemical vapor deposition process comprises:
a first chemical vapor deposition stage comprising adding first impurities in said chemical vapor deposition process;
a second chemical vapor deposition stage comprising depositing polysilicon; and
a third chemical vapor deposition stage comprising adding second impurities in said chemical vapor deposition process,
wherein said first impurities and said second impurities comprise one of NH₃, Methyl Silane, C₂H₆, Germanium, and a mixture of BTBAS and SiH₄.

5. The method according to claim 4, wherein said adding of said impurities comprises:
pausing said chemical vapor deposition process;
adding said impurities; and
restarting said chemical vapor deposition process.

6. (canceled)
